(19) United States
(12) Patent Application Publication
(10) Pub. No.: US 2026/0075860 A1
(43) Pub. Date: Mar. 12, 2026

(54) SIC FET WITH PROTON DOPING TO REDUCE INTERFACE DEFECTS

(71) Applicant: Microchip Technology Incorporated, Chandler, AZ (US)

(72) Inventors: Sami Alexandre El Hageali, Castle Rock, CO (US); Shesh Mani Pandey, Gilbert, AZ (US)

(73) Assignee: Microchip Technology Incorporated, Chandler, AZ (US)

(21) Appl. No.: 19/247,524

(22) Filed: Jun. 24, 2025

Related U.S. Application Data
(60) Provisional application No. 63/691,746, filed on Sep. 6, 2024.

(51) Int. Cl. H10D 30/01; H01L 21/04; H10D 30/66; H10D 62/10; H10D 62/832; H10D 62/834

(52) U.S. Cl. CPC H10D 30/0291; H10D 62/124; H10D 62/8325; H10D 62/834; H10P 30/2042; H10P 30/21; H10D 30/66

(57) ABSTRACT

A silicon carbide field-effect transistor is doped with protons to reduce interface defects, and a method of proton doping a silicon carbide field-effect transistor is provided to reduce interface defects. Various FET structures (e.g., source, body, well) may be implanted in a drift region at a first end of a volume of semiconductor material. A drain may be provided (e.g., at a second end of the volume of semiconductor material). In a first example, protons (H+ ions) may be implanted to create a doped region at the first end prior to depositing a dielectric material associated with a gate. The resulting doped interface region underlying the dielectric material exhibits a reduction in trapped charges. In a second example, the dielectric material is deposited prior to proton implantation. The resulting doped interface region exhibits the reduction in trapped charges, and the dielectric material exhibits a reduction in mobile ionic charges.

### RELATED APPLICATION

The present U.S. non-provisional patent application is related to and claims priority benefit of an earlier-filed U.S. provisional patent application titled “SiC FET with Proton Doping to Reduce Interface Defects,” Ser. No. 63/691,746, filed Sep. 6, 2024. The entire content of the identified earlier-filed application is incorporated by reference as if fully set forth herein.

### FIELD

The present disclosure relates to silicon carbide field-effect transistors and methods of making them, and more particularly, the various examples described herein concern a silicon carbide field-effect transistor with a proton doped region for reducing interface defects, and a method of proton doping a silicon carbide field-effect transistor to reduce interface defects.

### BACKGROUND

A field-effect transistor (FET), such as a metal oxide semiconductor field-effect transistor (MOSFET), is an active, voltage-controlled semiconductor device, in which varying a control electrical voltage controls an electrical current flowing through a semiconductor channel between a drain and a source. Applications for FETs include amplifiers, switches, resistors, regulators, oscillators, and choppers. It is generally desirable to improve the performance and reduce the cost of FETs, but it can be difficult to do so.

This background discussion is intended to provide related information, and is not necessarily prior art.

### SUMMARY

Examples provide a silicon carbide (SiC) FET with proton doping to reduce interface defects, and a method of proton doping a SiC FET to reduce interface defects. Broadly, examples implant protons, such as hydrogen ions (H+), (i.e., perform proton doping) in an upper region of a drift layer at the interface with a dielectric material layer. The drift layer may be a 4H-SiC epilayer, and the dielectric material may be a silicon dioxide (SiO2) gate oxide. Proton doping may be performed prior to or after the introduction of the gate oxide. Examples advantageously improve the performance of SiC FET devices with high blocking voltages by reducing the defect density, reducing the capture of carriers by defects during switching, and increasing the charge density, and thereby improving the electrical properties of the devices.

In an example, a method of proton doping a SiC FET to reduce interface defects may include the following operations. A volume of silicon carbide (SiC) semiconductor material may be provided, wherein the volume of SiC semiconductor material may have a first end and a second end. A plurality of field-effect transistor structures may be provided adjacent the first end of the volume of SiC semiconductor material. A layer of dielectric material of a gate may be provided. A plurality of protons are implanted into a region of the volume of SiC semiconductor material adjacent to the plurality of field-effect transistor structures to create a proton doped region which is adjacent to the layer of dielectric material.

The preceding example may further include any one or more of the following features. The step of providing the layer of dielectric material may include growing the layer of dielectric material along a portion of the volume of silicon carbide semiconductor material. The step of growing the layer of dielectric material may include locating the layer of dielectric material along the first end of the volume of silicon carbide semiconductor material. The step of implanting the plurality of protons may include locating the proton doped region along the first end of the volume of silicon carbide semiconductor material in an underlying relationship relative to the layer of dielectric material. The step of implanting the plurality of protons may include locating the proton doped region in an underlying relationship relative to the layer of dielectric material. The of providing the plurality of field-effect transistor structures may include implanting a source at the first end of the volume of silicon carbide semiconductor material, wherein the source includes spaced apart source segments. The step of providing the layer of dielectric material may include extending the layer of dielectric material continuously between the source segments. The step of implanting the plurality of protons may include extending the proton doped region continuously between the source segments. The step of implanting the plurality of protons may be performed prior to the step of providing the layer of dielectric material. The step of implanting the plurality of protons may be performed after the step of providing the layer of dielectric material, such that the plurality of protons are implanted through the layer of dielectric material. The step of implanting the plurality of protons may be performed at an irradiation temperature of room temperature, a proton fluence of between 10\hat{ }10 and 10\hat{ }15 H+/cm\hat{ }2, and a proton energy of between 5 and 100 keV. The step of providing the volume of silicon carbide semiconductor material may include growing a silicon carbide buffer layer. The step of providing the volume of silicon carbide semiconductor material may include growing a silicon carbide drift region adjacent to the silicon carbide buffer layer. The method may also include providing a silicon carbide substrate on which the silicon carbide buffer layer is grown, wherein the silicon carbide substrate may be located at the second end of the volume of silicon carbide semiconductor material and may provide a drain. The silicon carbide substrate may be an N+ material. The silicon carbide buffer layer may be an N+ material. The silicon carbide drift region may be an N− material. The step of providing the plurality of field-effect transistor structures may include implanting a source at the first end of the volume of semiconductor material. The step of providing the plurality of field-effect transistor structures may include implanting a body contact adjacent the source. The step of providing the plurality of field-effect transistor structures may include implanting a well adjacent the source.

This summary is not intended to identify essential features of the examples, and is not intended to be used to limit the scope of the claims. These and other aspects of the present invention are described below in greater detail.

### DRAWINGS

Examples are described in detail below with reference to the attached drawing figures, wherein:

FIG. 1 is a cross-sectional elevation view of a volume of SiC N-type epitaxial semiconductor material which may be used to make a SiC FET;

FIG. 2 is a cross-sectional elevation view of the volume of semiconductor material of FIG. 1 in which various FET structures have been implanted or otherwise provided and a layer of dielectric material (associated with a gate structure) has not yet been deposited or otherwise introduced, wherein the device is ready for proton doping in accordance with a first example of the present disclosure;

FIG. 3 is a cross-sectional elevation view of the device of FIG. 2 after proton doping and introduction of the dielectric material;

FIG. 4 is a cross-sectional fragmentary depiction of an interface region between the dielectric material and a drift region of the device of FIG. 2 showing the result of proton doping;

FIG. 5 is a cross-sectional elevation view of the volume of semiconductor material of FIG. 1 in which various FET structures have been implanted or otherwise provided and the layer of dielectric material (associated with a gate structure) has been deposited or otherwise introduced, wherein the device is ready for proton doping in accordance with a second example of the present disclosure;

FIG. 6 is a cross-sectional fragmentary depiction of an interface region between the dielectric material and the drift region of the device of FIG. 5 showing the result of proton doping; and

FIG. 7 is a flowchart of operations in an example of a method of proton doping a SiC FET to reduce interface defects, including the first and second examples of FIGS. 2 and 5.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

The reliability and performance of SiC FET devices is reduced by interface trap defects at an interface of a dielectric material (e.g., SiO2) and the adjacent volume of semiconductor material (e.g., 4H-SiC). There may be a substantial number of such traps at this interface. SiO2/4H-SiC is, by its nature, crystallographically non-homogeneous, so it is not possible to form a fully-bonded interface primarily due to lattice mismatch. This mismatch induces a large number of interface charges commonly referred to as interface trap or defect density (Dit). These interface traps create a shallow near-conduction band-edge shift within the forbidden gap at the heterointerface, which has a polarization effect that, like a capacitor, stores charges during device turn-on/off cycles. Attempts have been made to use nitrogen-based gas chemistries to passivate this interface, but this has not fully resolved the reliability problem of these devices and the impact of these defects on device performance.

Examples provide a SiC FET with proton doping to reduce interface defects, and a method of proton doping a SiC FET to reduce interface defects. Broadly, examples implant protons, such as hydrogen ions (H+), (i.e., perform proton doping) along the interface defined between the dielectric material layer and the volume of SiC semiconductor material. The volume of SiC semiconductor material may be a 4H-SiC epilayer, and the dielectric material may be an SiO2 gate oxide. Proton doping may be performed prior to or after the introduction of the gate oxide. Examples advantageously improve the performance of SiC FET devices with high blocking voltages by reducing Dit, reducing the capture of carriers by defects during switching, and increasing the charge density, and thereby improving the electrical properties of the devices.

The proton implantation, or irradiation, may be performed under suitable irradiation temperature (e.g., approximately room temperature), proton fluence (e.g., approximately between 10\hat{ }10 and 10\hat{ }15 H+/cm\hat{ }2), and proton energy (e.g., approximately between 5 and 100 keV) conditions. Fluence, or radiant exposure, is the radiant energy received by a surface per unit area. The incident protons may fill the inherent point defects (i.e., vacancies) at the interface, thereby reducing the defect density. Further, the gate leakage current is reduced and the maximum saturation current and transconductance of the FET device is increased, thereby further improving the electrical performance of the device. The proton implant may also reduce the thermal hopping of point defects, thereby enhancing carrier lifetime and preventing defect accumulation through migration.

During the proton implantation process, which is dominated by Coulomb interactions, non-ionization energy loss may affect the SiC FET device. The greater the non-ionization energy loss, the greater the damage to the device, and the non-ionization energy loss is inversely proportional to the implanted proton energy. Therefore, a higher proton energy selected within a given range results in greater non-ionization energy loss, and a smaller ionization energy loss results in less radiation damage to the device. In the process of proton implantation, proton fluence has a greater impact on device performance than the damage caused by proton energy. Therefore, if the proton fluence exceeds a given range, the electrical properties of the device may be significantly deteriorated. When the appropriate proton fluence and proton energy are selected, proton irradiation/implantation can effectively improve the electrical performance of the device.

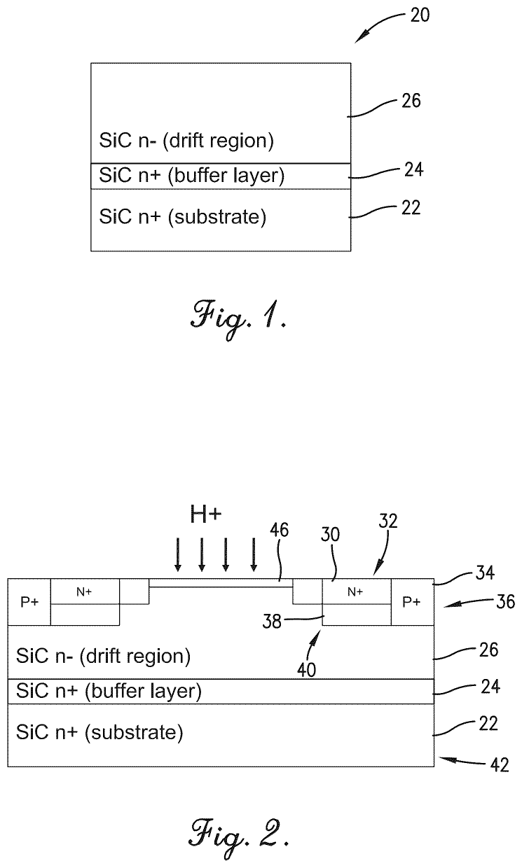

Referring to FIG. 1, a volume of semiconductor material 20 is shown. In the illustrated example, the volume of semiconductor material is epitaxially grown silicon carbide (SiC) which may be used to make a SiC FET device with proton doping to reduce interface defects. The semiconductor material 20 may be N-type material and may be provided on a SiC N+ substrate material 22. The semiconductor material 20 may have a first end, second end, a first side, and a second side, with the N+ substrate material 22 being located at the second end. The semiconductor material 20 may include various layers or regions, such as a SiC N+ buffer layer 24 above or otherwise adjacent to the substrate 22, and an SiC N− drift region 26 above or otherwise adjacent to the buffer layer 24. The drift region 26 may generally be understood to include the portion of the volume of semiconductor material 20 above the buffer layer 24 and outside the FET structures (or components), which are further described in the next paragraph.

Referring also to FIG. 2, in a first example of a SiC FET device with proton doping to reduce interface defects, various FET structures may be implanted (using, e.g., an ion implanter) or otherwise provided in the drift region 26 of the semiconductor material 20 of FIG. 1. These structures may vary depending on the type of FET, and may include an N+ material 30 for a source 32 at the first end of the semiconductor material 20, a P+ material 34 for a body 36 adjacent to the source 32, and a P+ material 38 for a P-well 40 below or otherwise adjacent to the source 32. As noted more specifically below, the polarity of the SiC semiconductor material and the FET components may be reversed so as to provide a P-channel FET. As shown in FIG. 2, different, similar, or identical materials and structures may be provided, spaced apart, at the first and second sides of the semiconductor material 20, depending on the design of the FET. For example, the illustrated FET is a dual channel device, wherein each FET structure or component is segmented to present spaced apart mirror images of one another. More particularly, each source segment 32 and the corresponding well segment 40 are associated with a respective channel extending between the source and the drain. However, according to some aspects of the present disclosure, the FET may alternatively be constructed to provide a single channel (wherein the cell unit includes only a single source and a single well).

The N+ substrate 22, which is located at the second end of the semiconductor material 20 opposite the source 32, may provide a drain 42. According to certain aspects of the present disclosure, the drain may be alternatively located along the semiconductor material, such as at the first end.

In this first example, a layer of dielectric material associated with a gate has not yet been deposited or otherwise provided (e.g., by thermal oxidation) on the first end of the semiconductor material 20. Protons (H+ ions) may be implanted to create a proton-doped interface region 46 along the first end of the semiconductor material 20 in a process of proton doping. The proton-doped region 46 may extend continuously between the sides of the volume of semiconductor material. However, in other examples, the proton-doped region may extend continuously between only the source segments. In both examples, a portion of the proton-doped region extends along the top of the well segments 40. However, in yet further examples, the proton doped region may extend along only the drift region 26 defined between the well segments 40. The location of the proton-doped region may be coextensive with the layer of dielectric material so as to improve the dielectric/SiC interface. For instance, in an example where a split gate (not shown) is provided such that a space is provided between spaced apart segments of the layer of dielectric material, the portion of the drift region 26 defined between the spaced apart segments of dielectric material (e.g., between the well segments 40) may not be implanted with protons.

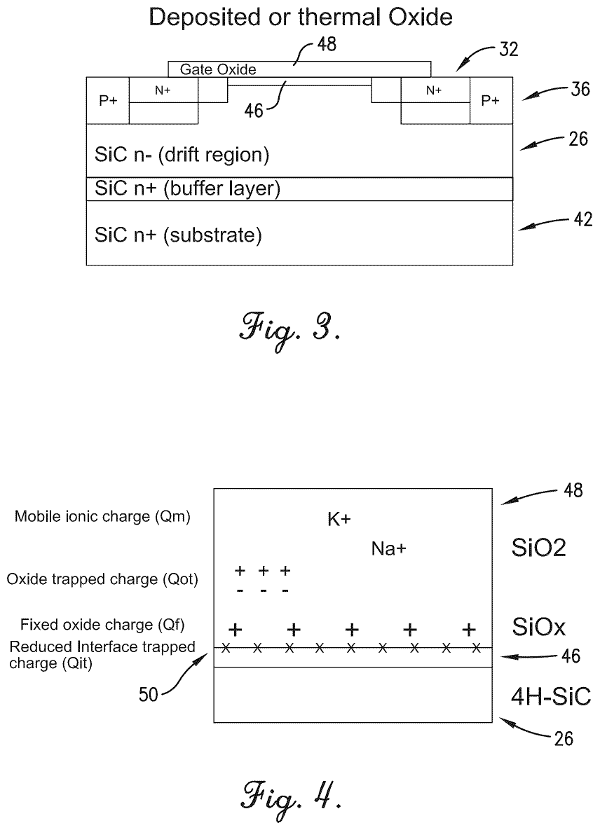

Referring also to FIG. 3, after proton doping, the dielectric material 48, which may be a gate oxide such as SiO2, may be deposited or otherwise provided (e.g., by thermal oxidation) over the doped region 46 at the first end of the semiconductor material 20. Referring also to FIG. 4, the doped region 46 between the dielectric material 48 and the drift region 26 shows the results of proton doping, including a reduction in trapped charges, Qit, in the interface region 50. It is further noted that the example FET shown in FIG. 3 is a planar FET with the gate being defined along (essentially above) the first end of the volume of semiconductor material 20. However, according to some examples, the FET may alternative have a trench configuration (not shown), such that the gate and at least a portion dielectric material is located within a trench extending inwardly from the first end of the volume of semiconductor material. In such an alternative, the proton-doped region is provided along the surfaces of the trench along which the layer of dielectric material extends. In either the planer or trench FET configurations, the proton-doped region may be in an underlying relationship of the dielectric material (e.g., so that the proton-doped region and the layer of dielectric material are coextensive).

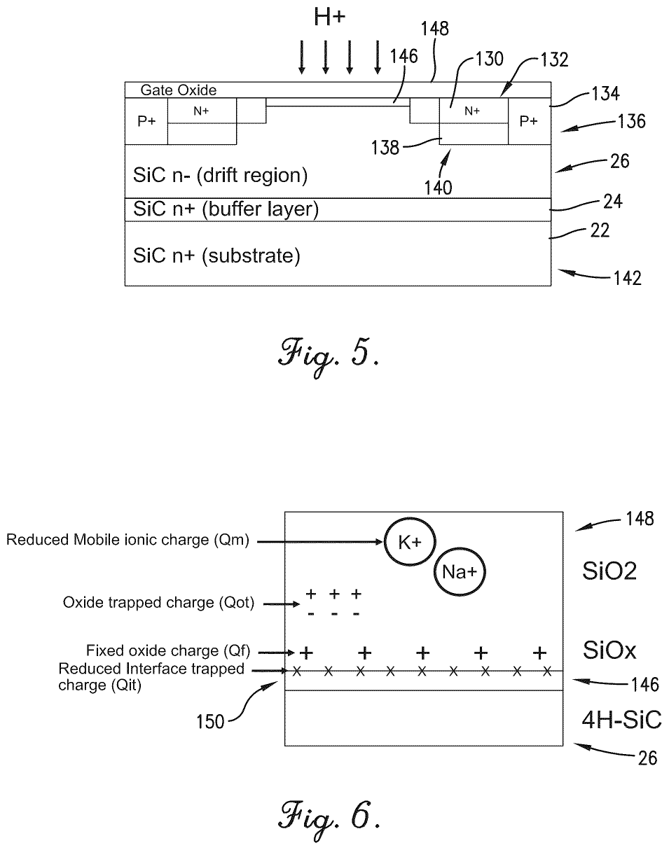

Referring to FIG. 5, in a second example of a SiC FET with proton doping to reduce interface defects, various FET structures may be implanted (using, e.g., an ion implanter) or otherwise provided in the drift region 26 of the semiconductor material 20 of FIG. 1. These structures may vary depending on the type of FET, but may include an N+ material 130 for a source 132 at the first end of the semiconductor material 20, a P+ material 134 for a body 136 adjacent to the source 132, and a P+ material 138 for a P-well 140 below or otherwise adjacent to the source 132. The N+ substrate 122, which is located at the second end of the semiconductor material 20 opposite the source 132, may provide a drain 142. Similar to the first example, these materials and structure may be repeated on an opposite side of the volume semiconductor material 20. The various other features and alternative arrangements noted above with respect to the first example may be incorporated in this example.

In this second example, the layer of dielectric material associated with the gate is deposited or otherwise provided on the first end of the semiconductor material 20 prior to proton implantation. Protons (H+ ions) may be implanted to create the proton-doped interface region 146 in the drift region 26 at the first end of the semiconductor material 20. Referring also to FIG. 6, the doped region 146 between the dielectric material 148 and the drift region 26 shows the results of proton doping, including the reduction in Qit in the interface region 150. Further, by implanting the protons through the gate oxide 148, the second example also reduces the mobile ionic charges in the gate oxide 148.

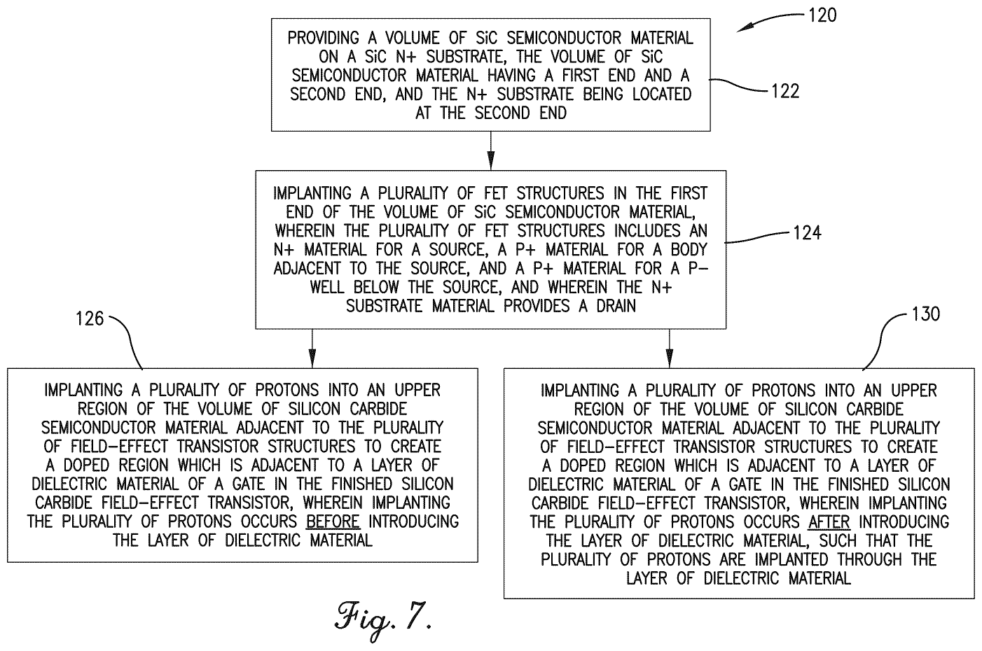

Referring to FIG. 7, an example of a method 120 of proton doping a SiC FET to reduce interface defects may include the operations set forth below. Reference is made to the first and second example SiC FETs 20, 120 described above. A volume of SiC N-type epitaxial semiconductor material 20 may be grown or otherwise provided on a SiC N+ substrate material 22, as shown in 122 and seen in FIG. 1. The semiconductor material 20 may have a first end and second end, with the N+ substrate material 22 being located at the second end. The semiconductor material 20 may include various layers or regions, such as a SiC N+ buffer layer 24 adjacent to the substrate 22, and a SiC N-drift region 26 adjacent to the buffer layer 24.

Various FET structures may be implanted (using, e.g., an ion implanter) or otherwise provided in the drift region 26 of the semiconductor material 20, as shown in 124 and seen in FIGS. 2 and 5. These structures may vary depending on the type of FET, but may include an N+ material 30, 130 for a source 32, 132 at the first end of the semiconductor material 20; a P+ material 34, 134 for a body 36, 136 adjacent to the source 32, 132; and a P+ material 38, 138 for a P-well 40, 140 below or otherwise adjacent to the source 32. The N+ substrate 22, which is located at the second end of the semiconductor material 20 opposite the source 32, 132 may provide a drain 42, 142. These materials and structure may be repeated on an opposite side of the volume semiconductor material 20.

In a first example, protons (H+ ions) may be implanted to create a proton-doped interface region 46 in the drift region 26 at the first end of the semiconductor material 20 in a process of proton prior to depositing or otherwise providing a layer of dielectric material associated with a gate, as shown in 126 and seen in FIG. 2. Proton implantation may be performed at an irradiation temperature of approximately room temperature, a proton fluence of approximately between 10\hat{ }10 and 10\hat{ }15 H+/cm\hat{ }2, and a proton energy of approximately between 5 and 100 keV. After proton doping, the dielectric material 48, which may be a gate oxide such as SiO2, may be deposited of otherwise provided over the doped region 46 at the first end of the semiconductor material 20, as shown in 128 and seen in FIG. 3. The resulting doped interface region 46 between the dielectric material 48 and the drift region 26 exhibits a reduction in Qit in the interface region 50, as seen in FIG. 4. Additional operations may be performed as desired.

In a second example, the layer of dielectric material associated with the gate may be deposited or otherwise provided on the first end of the semiconductor material 20 prior to proton implantation, as shown in 130 and seen in FIG. 5. Protons (H+ ions) may be implanted to create a proton-doped interface region 146 in the drift region 26 at the first end of the semiconductor material 20 in a process of proton doping, as shown in 132 and seen in FIG. 5. Proton implantation may be performed at an irradiation temperature of approximately room temperature, a proton fluence of approximately between 10 \hat{ }10 and 10\hat{ }15 H+/cm\hat{ }2, and a proton energy of approximately between 5 and 100 keV. The resulting doped interface region 146 between the dielectric material 148 and the drift region 26 shows the results of proton doping, including the reduction in Qit in the interface region 150, as seen in FIG. 6. Further, by implanting the protons through the gate oxide 148, the second example also reduces the mobile ionic charges in the gate oxide 148, as also seen in FIG. 6.

Additional operations may be performed as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }≠and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right or left side of a volume of semiconductor material may be to the conceptual limit of a particular unit cell and not to an actual physical end of the material.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A method of proton doping a silicon carbide field-effect transistor to reduce interface defects, the method comprising:
providing a volume of silicon carbide semiconductor material, the volume of silicon carbide semiconductor material having a first end and a second end;
providing a plurality of field-effect transistor structures adjacent the first end of the volume of silicon carbide semiconductor material;
providing a layer of dielectric material of a gate; and
implanting a plurality of protons into a region of the volume of silicon carbide semiconductor material adjacent to the plurality of field-effect transistor structures to create a proton doped region which is adjacent to the layer of dielectric material.

2. The method of claim 1,
the step of providing the layer of dielectric material includes growing the layer of dielectric material along a portion of the volume of silicon carbide semiconductor material.

3. The method of claim 2,
the step of growing the layer of dielectric material includes locating the layer of dielectric material along the first end of the volume of silicon carbide semiconductor material,
the step of implanting the plurality of protons includes locating the proton doped region along the first end of the volume of silicon carbide semiconductor material in an underlying relationship relative to the layer of dielectric material.

4. The method of claim 2,
the step of implanting the plurality of protons includes locating the proton doped region in an underlying relationship relative to the layer of dielectric material.

5. The method of claim 4,
the step of providing the plurality of field-effect transistor structures includes implanting a source at the first end of the volume of silicon carbide semiconductor material, wherein the source includes spaced apart source segments,
the step of growing the layer of dielectric material includes extending the layer of dielectric material continuously between the source segments,
the step of implanting the plurality of protons includes extending the proton doped region continuously between the source segments.

6. The method of claim 4,
the step of implanting the plurality of protons being performed prior to the step of growing the layer of dielectric material.

7. The method of claim 4,
the step of implanting the plurality of protons being performed after the step of growing the layer of dielectric material, such that the plurality of protons are implanted through the layer of dielectric material.

8. The method of claim 4,
the step of implanting the plurality of protons being performed at an irradiation temperature of room temperature, a proton fluence of between 10\hat{ }10 and 10\hat{ }15 H+/cm\hat{ }2, and a proton energy of between 5 and 100 keV.

9. The method of claim 4,
the step of providing the volume of silicon carbide semiconductor material includes growing a silicon carbide buffer layer,
the step of providing the volume of silicon carbide semiconductor material includes growing a silicon carbide drift region adjacent to the silicon carbide buffer layer.

10. The method of claim 9, comprising:
providing a silicon carbide substrate on which the silicon carbide buffer layer is grown, wherein the silicon carbide substrate is located at the second end of the volume of silicon carbide semiconductor material and provides a drain.

11. The method of claim 9, wherein the silicon carbide substrate is an N+ material, the silicon carbide buffer layer is an N+ material, and the silicon carbide drift region is an N− material.

12. The method of claim 9,
the step of providing the plurality of field-effect transistor structures includes implanting a source at the first end of the volume of semiconductor material, implanting a body contact adjacent the source, and implanting a well adjacent the source.

13. The method of claim 12, wherein the silicon carbide buffer layer is an N+ material, the silicon carbide drift region is an N− material, the source includes an N+ material, the body contact includes a P+ material, and the well includes a P+ material.

14. The method of claim 1,
the step of implanting the plurality of protons being performed prior to the step of providing the layer of dielectric material.

15. The method of claim 1,
the step of implanting the plurality of protons being performed after the step of providing the layer of dielectric material, such that the plurality of protons are implanted through the layer of dielectric material.

16. The method of claim 1,
the step of implanting the plurality of protons being performed at an irradiation temperature of room temperature, a proton fluence of between 10\hat{ }10 and 10\hat{ }15 H+/cm\hat{ }2, and a proton energy of between 5 and 100 keV.

17. The method of claim 1,
the step of providing the volume of silicon carbide semiconductor material includes growing a silicon carbide buffer layer,
the step of providing the volume of silicon carbide semiconductor material includes growing a silicon carbide drift region adjacent to the silicon carbide buffer layer.

18. The method of claim 17, comprising:
providing a silicon carbide substrate on which the silicon carbide buffer layer is grown, wherein the silicon carbide substrate is located at the second end of the volume of silicon carbide semiconductor material and provides a drain.

19. The method of claim 1,
the step of providing the plurality of field-effect transistor structures includes implanting a source at the first end of the volume of silicon carbide semiconductor material, implanting a body contact adjacent the source, and implanting a well adjacent the source.

20. The method of claim 19, wherein the volume of silicon carbide semiconductor material is an N material, the source includes an N material, the body contact includes a P material, and the well includes a P material.
